(19) United States
(12) Patent Application Publication
(10) Pub. No.: US 2018/0032780 A1
(43) Pub. Date: Feb. 1, 2018

(54) FINGERPRINT DETECTION CIRCUIT AND ELECTRONIC DEVICE

(71) Applicant: BYD COMPANY LIMITED, Shenzhen (CN)

(72) Inventors: Zhengang LI, Shenzhen (CN); Kunping XU, Shenzhen (CN); Yun YANG, Shenzhen (CN)

(21) Appl. No.: 15/549,872

(22) PCT Filed: Jan. 5, 2016
(86) PCT No.: PCT/CN2016/070195

§ 371 Date: Aug. 9, 2017

(30) Foreign Application Priority Data
Feb. 13, 2015 (CN) 201510082139.X

(51) Int. Cl. G06K 9/00; H03F 3/00

(52) U.S. Cl. CPC G06K 9/0002; H03F 3/005; H03F 2200/129

(57) ABSTRACT

A fingerprint detection circuit and an electronic device are provided. The fingerprint detection circuit is configured to apply an excitation signal to a finger so as to generate a finger capacitor, and the fingerprint detection circuit includes: a signal amplifier having a negative input terminal connected with the finger capacitor, a positive input terminal connected with a voltage reference terminal, and an output terminal to output an output voltage according to a capacitance value of the finger capacitor; a capacitor; and a switch unit connected with the negative input terminal and the output terminal of the signal amplifier respectively, and configured to control the capacitor to be connected between the negative input terminal and the output terminal of the signal amplifier, such that the output voltage has a non-linear relationship with the capacitance value of the finger capacitor.

### CROSS REFERENCE TO RELATED APPLICATIONS

This application claims priority and benefits of Chinese Patent Application No. 201510082139.X, filed with State Intellectual Property Office, P. R. C. on Feb. 13, 2015, the entire content of which is incorporated herein by reference.

### FIELD

The present disclosure relates to a fingerprint detection technology field and, more particularly, to a fingerprint detection circuit and an electronic device.

### BACKGROUND

In the related art, since a capacitive fingerprint detection circuit in a chip has advantages of small size and low power consumption, this kind of the fingerprint detection circuit is more preferred in a market of mobile phones and tablets.

The above capacitive fingerprint detection circuit detects fingerprint ridge information and fingerprint valley information. Since the distance between the fingerprint ridge and a sensing unit of the fingerprint detection unit is relatively close, and the distance between the fingerprint valley and the sensing unit of the fingerprint detection unit is relatively far, there is a difference between a ridge capacitance generated between the fingerprint ridge and the sensing unit and a valley capacitance generated between the fingerprint valley and the sensing unit. Once the ridge capacitance and the valley capacitance (referred to finger capacitance hereinafter) are detected, ridge characteristics and valley characteristics of the finger may be analyzed.

An output voltage output from the above fingerprint detection circuit has a proportional linear relationship with the finger capacitance (capacitance to be tested). A final result has a small difference between an output voltage corresponding to the finger capacitance of the ridge and an output voltage corresponding to the finger capacitance of the valley, so that it needs to amplify an output voltage corresponding to the finger capacitance by a predetermined factor for processing. However, the amplified factor can be limited by a range, if the amplified factor is too large, the output voltage may exceed the range to cause the data to overflow, if the amplified factor is too small, and the calculated difference between the output voltage corresponding to the finger capacitance of the ridge and the output voltage corresponding to the finger capacitance of the valley is too small, which is too difficult to identify, and the finger detection result cannot be optimized.

### SUMMARY

Embodiments of the present disclosure seek to solve at least one of the problems existing in the related art to at least some extent.

The present disclosure provides a fingerprint detection circuit, and an electronic device.

According to embodiments of a first aspect of the present disclosure, a fingerprint detection circuit is provided. The fingerprint detection circuit is configured to apply an excitation signal to a finger so as to generate finger capacitors, the fingerprint detection circuit including: a signal amplifier having a negative input terminal connected with one of the finger capacitors, a positive input terminal connected with a voltage reference terminal, and an output terminal to output an output voltage according to a capacitance value of one of the finger capacitor; a capacitor; and a switch unit connected with the negative input terminal and the output terminal of the signal amplifier respectively, and configured to control the capacitor to be connected between the negative input terminal and the output terminal of the signal amplifier, such that the output voltage has a non-linear relationship with the capacitance value of one of the finger capacitors.

With the fingerprint detection circuit according to embodiments of the present disclosure, the output voltage of the signal amplifier has a non-linear relationship with the capacitance value of one of the finger capacitors, in the subsequent process, the output voltage of the signal amplifier can be amplified in a locally linear, such that the difference between the voltage corresponding to the ridge capacitor and the voltage corresponding to the valley capacitor becomes relatively large, and the signal to noise ratio is higher, which is easier for subsequent algorithms to recognize, thus improving the effect of the fingerprint detection.

According to embodiments of a second aspect of the present disclosure, an electronic device is provided, and the electronic device includes the fingerprint detection circuit according to embodiments of the first aspect of the present disclosure.

With the electronic device according to embodiments of the present disclosure, the output voltage of the signal amplifier has a non-linear relationship with the capacitance value of one of the finger capacitors, in the subsequent process, the output voltage of the signal amplifier can be amplified in a locally linear, such that the difference between the voltage corresponding to the ridge capacitor and the voltage corresponding to the valley capacitor becomes relatively large, and the signal to noise ratio is higher, which is easier for subsequent algorithms to recognize, thus improving the effect of the fingerprint detection.

The attached aspects and advantages of the present disclosure will be presented in following descriptions, and parts of which will become obviously in following descriptions, or learn by practice of the present disclosure.

### BRIEF DESCRIPTION OF THE DRAWINGS

These and other aspects and advantages of embodiments of the present disclosure will become apparent and more readily appreciated from the following descriptions made with reference to the drawings, in which:

FIG. 1 is a schematic diagram of a fingerprint detection circuit according to an exemplary embodiment of the present disclosure;

FIG. 2 is a schematic diagram illustrating a fingerprint collecting operation performed by the fingerprint detection circuit according to an exemplary embodiment of the present disclosure;

FIG. 3 is a schematic diagram of a fingerprint detection circuit according to another exemplary embodiment of the present disclosure; and

FIG. 4 is a schematic diagram of an electronic device according to an exemplary embodiment of the present disclosure.

### DETAILED DESCRIPTION

Exemplary embodiments will be described in detail herein, and examples thereof are illustrated in accompanying drawings. Reference will be made in detail to embodiments of the present disclosure. The embodiments described herein with reference to drawings are explanatory, illustrative, and used to generally understand the present disclosure. The embodiments shall not be construed to limit the present disclosure. The same or similar elements and the elements having same or similar functions are denoted by like reference numerals throughout the descriptions.

In the description of the present disclosure, it should be understood that, terms such as “first” and “second” are used herein for purposes of description and are not intended to indicate or imply relative importance or significance or to imply the number of indicated technical features. Thus, the feature defined with “first” and “second” may comprise one or more of this feature. In the description of the present invention, “a plurality of” means two or more, unless specified otherwise.

In the description of the present disclosure, it should be understood that, unless specified or limited otherwise, the terms “mounted,” “connected,” and “coupled” and variations thereof are used broadly and encompass such as mechanical or electrical mountings, connections and couplings, also can be inner mountings, connections and couplings of two components, and further can be direct and indirect mountings, connections, and couplings, which can be understood by those skilled in the art according to the detail embodiment of the present disclosure.

Various embodiments and examples are provided in the following description to implement different structures of the present disclosure. In order to simplify the present disclosure, certain elements and settings will be described. However, these elements and settings are only by way of example and are not intended to limit the present disclosure. In addition, reference numerals may be repeated in different examples in the present disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied.

In the following, a fingerprint detection circuit, and an electronic device are described in detail with reference to drawings.

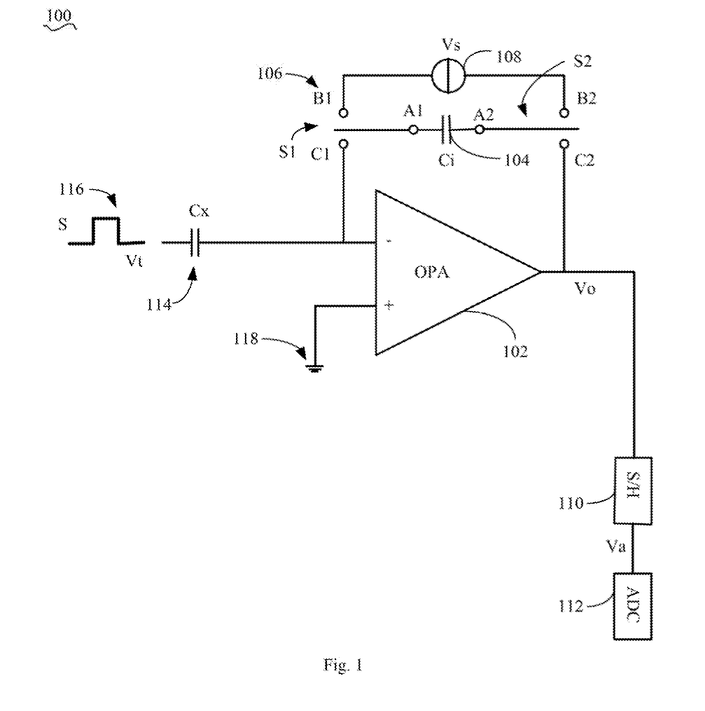

FIG. 1 is a schematic diagram of a fingerprint detection circuit according to an exemplary embodiment of the present disclosure. As shown in FIG. 1, the fingerprint detection circuit 100 includes a signal amplifier 102, a capacitor 104, and a switch unit 106.

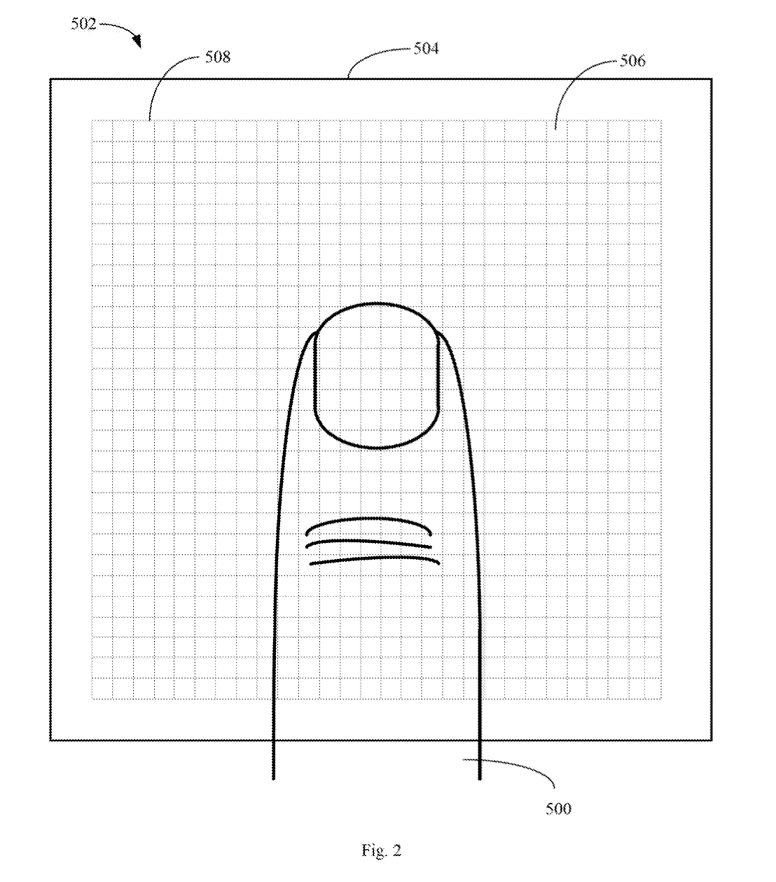

When collecting fingerprints (see FIG. 2), the fingerprint detection circuit 100 may apply an excitation signal to a finger 500 so as to generate finger capacitors 114. For example, the fingerprint detection circuit 100 may output the excitation signal via a signal generator 116, and transmit the excitation signal to the finger 500 via an emission electrode (not shown). The excitation signal may be an alternating signal, such as a sine-wave signal, a square wave signal, or a triangular wave signal. The voltage magnitude of the alternating signal (referred to excitation voltage hereinafter) is Vt, and the frequency of the alternating signal is S.

The finger capacitors 114 are generated between a fingerprint of the finger 500 and a fingerprint sensor 502. For example, the ridge capacitors are generated between a fingerprint ridge of the finger 500 and a fingerprint sensor 502, and the valley capacitors are generated between a fingerprint valley of the finger 500 and the fingerprint sensor 502. Each of the ridge capacitors and the valley capacitors can be referred to as the finger capacitor 114, which is a capacitor to be measured.

For example, as shown in FIG. 2, the fingerprint sensor 502 includes a frame 504 and a two-dimensional detecting array 508 including a plurality of fingerprint sensing units 506.

The frame 504 is arranged around the two-dimensional detecting array 508, and provides the excitation signal (such as the alternating signal) when the fingerprint detecting is performed. For example, the frame 504 may be connected with the emission electrode for outputting the excitation signal.

Each fingerprint sensing unit 506 is configured to collect a single pixel of a fingerprint image. For example, each fingerprint sensing unit 506 usually has a size of about 50 um*50 um. A capacitance value of the finger capacitor 114 generated between the fingerprint sensing unit 506 and the finger 500 is a ridge characteristic or a valley characteristic of the fingerprint. Therefore, by detecting the capacitance values of a plurality of finger capacitors 114, each of which is generated between one fingerprint sensing unit 506 and the finger 500, the ridge and valley characteristics of the fingerprint image can be analyzed according to the plurality of finger capacitors 114.

In an embodiment, as shown in FIG. 1, the signal amplifier 102 is corresponding to each fingerprint sensing unit 506 and outputs the output voltage corresponding to the finger capacitor 114. The negative input terminal of the signal amplifier 102 is connected with the finger capacitor 114, and the positive input terminal of the signal amplifier 102 is connected with a voltage reference terminal 118. The signal amplifier 102 is configured to output the output voltage from the output terminal of the signal amplifier 102 according to a capacitance value of the finger capacitor 114.

In an embodiment, the voltage reference terminal 118 is a ground terminal, that is, the positive input terminal of the signal amplifier 102 is connected with the ground terminal.

In an embodiment, the capacitor 104 may be an inner capacitor of the fingerprint sensor or other capacitors, and the capacitance value of the capacitor 104 is usually fixed.

The switch unit 106 is connected with the negative input terminal of the signal amplifier 102 and the output terminal of the signal amplifier 102 respectively, and is configured to control the capacitor 104 to be connected between the negative input terminal of the signal amplifier 102 and the output terminal of the signal amplifier 102, such that the output voltage has a non-linear relationship with the capacitance value of the finger capacitor 114.

In an embodiment, the first power supply 108 is connected with the capacitor 104 via the switch unit 106, and the switch unit 106 is configured to control the first power supply 108 to charge the capacitor 106 or control the capacitor 106 to disconnect from the first power supply 108. The first power supply 108 may be an inner power supply of the fingerprint detection circuit 100, for example, a first electrode of the first power supply 108 is a negative electrode, and a second electrode of the first power supply 108 is a positive electrode.

Furthermore, the switch unit 106 includes a first switch S1 and a second switch S2. The first switch S1 includes a first selecting terminal A1, a first power terminal B1 and a first connecting terminal C1, the first selecting terminal A1 is connected with a first terminal of the capacitor 104, the first power terminal B1 is connected with the first electrode of the first power supply 108, and the first connecting terminal C1 is connected with the negative input terminal of the signal amplifier 102. The second switch S2 includes a second selecting terminal A2, a second power terminal B2 and a second connecting terminal C2, the second selecting terminal A2 is connected with a second terminal of the capacitor 104, the second power terminal B2 is connected with the second electrode of the first power supply 108, and the second connecting terminal C2 is connected with the output terminal of the signal amplifier 102. The first selecting terminal A1 may be connected with the first connecting terminal C1 or the first power terminal B1, and the second selecting terminal A2 may be connected with the second connecting terminal C2 or the second power terminal B2. When the first selecting terminal A1 is connected with the first connecting terminal C1 and disconnected from the first power terminal B1, and the second selecting terminal A2 is connected with the second connecting terminal C2 and disconnected from the second power terminal B2, the capacitor 104 is connected between the negative input terminal of the signal amplifier 102 and the output terminal of the signal amplifier 102, and disconnected from the first power supply 108. When the first selecting terminal A1 is connected with the first power terminal B1 and disconnected from the first connecting terminal C, and the second selecting terminal A2 is connected with the second power terminal B2 and disconnected from the second connecting terminal C2, the first power supply 108 charges the capacitor 104, such that two terminals of the capacitor 104 have the certain voltage.

In an embodiment, as shown in FIG. 1, the fingerprint detection circuit 100 further includes a sampling hold (S/H) circuit 110 and an analog-to-digital converter (ADC) 112. The sampling hold circuit 110 is connected between the output terminal of the signal amplifier 102 and a terminal of the analog-to-digital converter 112. The sampling hold circuit 110 is configured to amplify the output voltage from the output terminal of the signal amplifier 102 by a predetermined factor. The analog-to-digital converter 112 is configured to convert an amplified output voltage to a numerical value and save the numerical value. The fingerprint detection circuit 100 may further include a digital signal processor (not shown) for processing digital signals, and the digital signal processor is connected with the output terminal of the analog-to-digital converter 112. The digitized voltages outputted from the signal amplifier 102 are convenient for following computation.

In an embodiment, the capacitance value of one of the finger capacitors is determined according to a formula of

Vo=(Vc−Vt*Cx/Ci),

where, Vo is the output voltage, Vt is an excitation voltage of the excitation signal, Cx is the capacitance value of the finger capacitor 114, Ci is the capacitance value of the capacitor 104, and Vc is an voltage between the first terminal and the second terminal of the capacitor 104. According to the above formula, the output voltage Vo of the signal amplifier 102 has the non-linear relationship with the capacitance value Cx of the finger capacitor 114.

For example, when the fingerprint detection circuit 100 is initialized, the first selecting terminal A1 is connected to the first power terminal B1, and the second selecting terminal A2 is connected to the second power terminal B2, the second power terminal B2 is connected to the positive terminal of the first power supply 108, the first power terminal B1 is connected to the negative terminal of the first power supply 108, the first power supply 108 charges the capacitor 104. After charging, the voltage over the capacitor 104 is Vc. In one embodiment, Vc=Vs, Vs is the voltage of the first power supply 108. During initialization, two terminals of the finger capacitor 114 are connected to the ground, and the signal generator 116 is connected to the ground (i.e. Vt is connected to the ground). Then, the first selecting terminal A1 is connected to the first connecting terminal C1, the second selecting terminal A2 is connected to the second selecting terminal C2, and the capacitor 104 is connected between the negative terminal of the signal amplifier 102 and the output terminal of the signal amplifier 102. At this time, the output voltage Vo from the output terminal of the signal amplifier 102 is equal to Vc, and the initialization is completed.

When the fingerprint detection circuit 100 collects the fingerprints, the signal generator 116 increases the excitation voltage Vt, and during the increasing of the excitation voltage Vt, the finger capacitor 114 is charged, where the electric quantity of charges is Q=Vt*Cx. Due to the virtual short and virtual off feature of the operational amplifier, the voltage outputted from the signal amplifier 102 will decrease, and the capacitor 104 is needed to charge with the same amount of charges, thus keeping the input terminal of the operational amplifier at the ground level. Then, the electric quantity charged to the capacitor 104 is (Vc−Vo)*Ci=Vt*Cx, and thus the voltage Vo outputted from the output terminal of the signal amplifier 102 is Vo=Vc−Vt*Cx/Ci. Then, the voltage Vo is amplified n times by the sampling hold circuit 110, and the final detection voltage inputted to the AD converter 112 is Va=n*(Vc−Vt*Cx/Ci).

For example, when the finger 500 is put on the fingerprint sensor 502, in a traditional detection, the first voltage corresponding to the ridge capacitor Vo1=−2V, and assuming that the second voltage corresponding to the valley capacitor is 15% less than the first voltage, the second voltage Vo2=−1.7V. If the input range of the AD converter 112 is 0˜−5V, then the sampling hold circuit 110 may amplify the first voltage and the second voltage by at most 2.5 times, i.e., the amplified first voltage Va1=−5V, the amplified second voltage Va2=−4.25V, and the difference Va1−Va2=−0.75V.

In an embodiment, when the fingerprint detection circuit 100 is used to collect fingerprint, and the initialized voltage over the capacitor 104 is assumed to be Vs=1.5V, then during detection, the first voltage Vo1=1.5=−2=−0.5V, and the second voltage Vo2=1.5−1.7=−0.2V. At this time, the sampling hold circuit 110 may amplify the first voltage and the second voltage 10 times, i.e., the amplified first voltage Va1=−5V, the amplified second voltage Va2=−2V, and the difference Va1−Va2=−3V, which is −3/−0.75=4 times greater than the above difference in the traditional detection. The second voltage is 60% less than the first voltage, which is 4 times greater than 15% in the traditional detection. Then, the difference between the amplified first voltage and the amplified second voltage is relatively large, and the signal to noise ratio is higher, which is easier for subsequent algorithms to recognize.

Therefore, taking the first voltage as an example, it can be determined whether the first voltage Vo1 is larger than or equal to −0.5V (the predetermined value), if yes, the first voltage is used to generate the fingerprint image. If no, the fingerprint detection circuit 100 can adjust at least one of the excitation voltage Vt and the voltage Vc between the capacitor 104 so as to adjust the output voltage Vo. The predetermined value setting can be considered the factors such as the range of the AD converter 112, the security range of the excitation voltage Vt and the voltage Vc between the capacitor 104.

With the fingerprint detection circuit 100 according to embodiments of the present disclosure, the output voltage of the signal amplifier 102 has a non-linear relationship with the capacitance value of one of the finger capacitors 114. In the subsequent process, the output voltage of the signal amplifier 102 can be amplified in a locally linear form, such that the difference between the voltage corresponding to the ridge capacitor and the voltage corresponding to the valley capacitor becomes relatively large, and the signal to noise ratio is higher, which is easier for subsequent algorithms to recognize, thus improving the effect of the fingerprint detection.

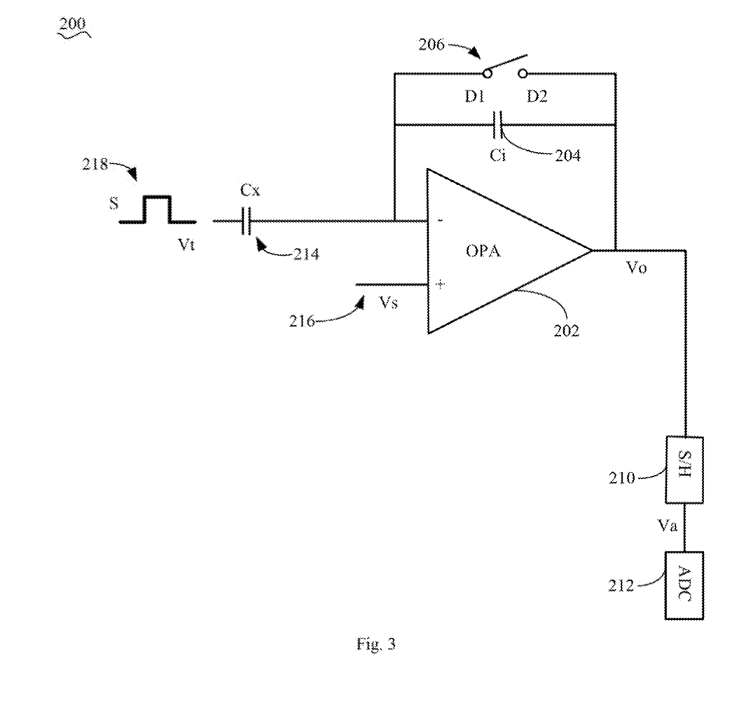

FIG. 3 is a schematic diagram of a fingerprint detection circuit according to another exemplary embodiment of the present disclosure. As shown in FIG. 3, the fingerprint detection circuit 100 includes a signal amplifier 202, a capacitor 204, a switch unit 206, a second power supply (not shown in FIG. 3), a sampling hold circuit 210 and an analog-to-digital converter 212.

When collecting fingerprints (see FIG. 2), the fingerprint detection circuit 200 may apply an excitation signal to a finger 500 by the fingerprint sensor 502 so as to generate finger capacitors 214.

The negative input terminal of the signal amplifier 202 is connected with one of the finger capacitors 214, the positive input terminal of the signal amplifier 202 is connected with the reference voltage terminal 216, the signal amplifier 202 outputs the output voltage from the output terminal of the signal amplifier 202 according to the capacitance of one of the finger capacitors 214.

In an embodiment, the reference voltage terminal 216 is the output terminal of the second power supply, that is, the positive terminal of the signal amplifier 202 is connected with the second power supply.

In an embodiment, the capacitor 204 may be an inner capacitor of the fingerprint sensor or other capacitors, and the capacitance value of the capacitor 204 is usually fixed.

The switch unit 206 is connected with the negative input terminal of the signal amplifier 202 and the output terminal of the signal amplifier 202 respectively, and is configured to control the capacitor 204 to be connected between the negative input terminal of the signal amplifier 202 and the output terminal of the signal amplifier 202, such that the output voltage has a non-linear relationship with the capacitance value of one of the finger capacitors 214.

In an embodiment, the switch unit 206 is connected with the capacitor 204 in parallel. When the switch unit 206 is turned off, the capacitor 204 is communicated with the negative input terminal of the signal amplifier 202 and the output terminal of the signal amplifier 202 respectively. That is, when the switch unit 206 is turned off, the capacitor 204 is in communication with the negative input terminal of the signal amplifier 202 and the output terminal of the signal amplifier 202 respectively. When the switch unit 206 is turned on, the capacitor 204 is disconnected between the negative input terminal of the signal amplifier 202 and the output terminal of the signal amplifier 202. The communication means connection and turn on. In this embodiment, the switch unit 206 is turned on, although the capacitor 204 is connected between the negative input terminal of the signal amplifier 202 and the output terminal of the signal amplifier 202, the capacitor 204 is shorted, the capacitor 204 cannot be communicated with the negative input terminal of the signal amplifier 202 and the output terminal of the signal amplifier 202 respectively.

In an embodiment, the switch unit 206 includes a first connecting terminal D and a second connecting terminal D2. The first connecting terminal D1 is connected between a first terminal of the capacitor 204 and the negative terminal of the signal amplifier 202. The second connecting terminal D2 is connected between a second terminal of the capacitor 204 and the output terminal of the signal amplifier 202. When the switch unit 206 is turned off, the capacitor 204 is communicated with the negative input terminal of the signal amplifier 202 and the output terminal of the signal amplifier 202 respectively. That is, the first connecting terminal D1 is disconnected from the second connecting terminal D2. When the switch unit 206 is turned off, the capacitor 204 is communicated with the negative input terminal of the signal amplifier 202 and the output terminal of the signal amplifier 202 respectively. That is, the first connecting terminal D1 is disconnected from the second connecting terminal D2. When the switch unit 206 is turned on, the capacitor 204 is disconnected between the negative input terminal of the signal amplifier 202 and the output terminal of the signal amplifier 202. That is, the first connecting terminal D1 is connected with the second connecting terminal D2, such that the output voltage from the output terminal of the signal amplifier 202 is equal to the voltage of the second power supply. The capacitor 204 is shorted and disconnected between the negative terminal and the output terminal of the signal amplifier 202, which has no effect to the output voltage from the output terminal of the signal amplifier 202.

In an embodiment, as shown in FIG. 3, the fingerprint detection circuit 200 further includes a sampling hold circuit 210 and an analog-to-digital converter 212. The sampling hold circuit 210 is connected between the output terminal of the signal amplifier 202 and a terminal of the analog-to-digital converter 212. The sampling hold circuit 210 is configured to amplify the output voltage from the output terminal of the signal amplifier 202 by a predetermined factor. The analog-to-digital converter 212 is configured to convert an amplified output voltage to a numerical value and save the numerical value. The fingerprint detection circuit 200 may further include a digital signal processor (not shown) for processing digital signals, and the digital signal processor is connected with the output terminal of analog-to-digital converter 212. The digitized voltages outputted from the signal amplifier 202 are convenient for following computation.

In an embodiment, the capacitance value of one of the finger capacitors is determined according to a formula of

Vo=(Vs−Vt*Cx/Ci),

where, Vo is the output voltage, Vt is an excitation voltage of the excitation signal, Cx is the capacitance value of the one of the finger capacitors 214, Ci is the capacitance value of the capacitor 204, and Vs is the voltage of the second power supply. According to the above formula, the output voltage Vo of the signal amplifier 202 has the non-linear relationship with the capacitance value Cx of one of the finger capacitors 214.

For example, when the fingerprint detection circuit 200 is initialized, the switch unit 206 is turned on, and two terminals of the finger capacitor 214 are connected to the ground during initialization. At this time, the output voltage Vo from the output terminal of the signal amplifier 102 is equal to Vs, and the initialization is completed.

When the fingerprint detection circuit 200 collects the fingerprints, the switch unit 206 is turned off, and the signal generator 218 increases the excitation voltage Vt, and during the increasing of the excitation voltage Vt, the finger capacitor 214 is charged, where the electric quantity of charges is Q=Vt*Cx. Due to the virtual short and virtual off feature of the operational amplifier, the voltage outputted from the signal amplifier 202 will decrease, and the capacitor 204 is needed to charge with the same amount of charges, thus keeping the input terminal of the operational amplifier at the ground level. Then, the electric quantity charged to the capacitor 204 is (Vs−Vo)*Ci=Vt*Cx, and thus the voltage Vo outputted from the output terminal of the signal amplifier 202 is Vo=Vs−Vt*Cx/Ci. Then, the voltage Vo is amplified n times by the sampling hold circuit 210, and the final detection voltage inputted to the AD converter 212 is Va=n*(Vc−Vt*Cx/Ci). Therefore, the output voltage Vo of the signal amplifier 202 is adjusting according to adjusting at least one of the excitation voltage Vt and the voltage of the capacitor 204.

With the fingerprint detection circuit 200 according to embodiments of the present disclosure, the output voltage of the signal amplifier 202 has a non-linear relationship with the capacitance value of one of the finger capacitor 214, in the subsequent process, the output voltage of the signal amplifier 202 can be amplified in a locally linear form, such that the difference between the voltage corresponding to the ridge capacitor and the voltage corresponding to the valley capacitor is relatively large, and the signal to noise ratio is higher, which is easier for subsequent algorithms to recognize, thus improving the effect of the fingerprint detection.

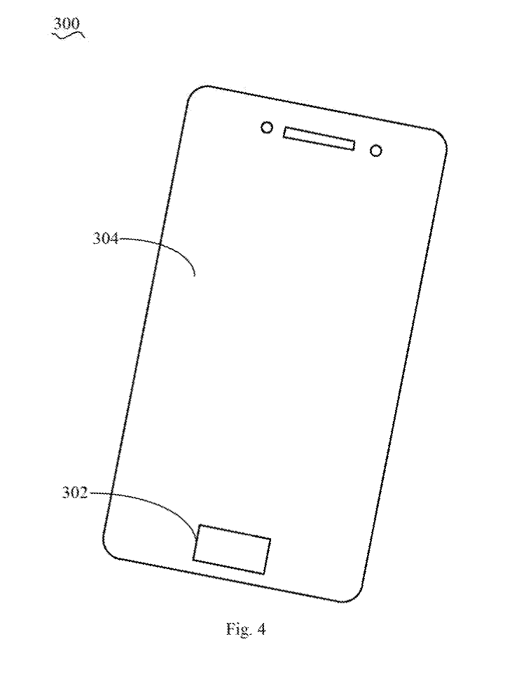

FIG. 4 is a schematic diagram of an electronic device according to an exemplary embodiment of the present disclosure. As shown in FIG. 4, the electronic device 300 includes a fingerprint detection circuit. The fingerprint detection circuit may be configured inside the electronic device 300. The fingerprint detection circuit may be any one of the above fingerprint detection circuits in the above embodiments.

With the electronic device according to embodiments of the present disclosure, the output voltage of the signal amplifier has a non-linear relationship with the capacitance value of one of the finger capacitor, in the subsequent process, the output voltage of the signal amplifier can be amplified in a locally linear, such that the difference between the voltage corresponding to the ridge capacitor and the voltage corresponding to the valley capacitor becomes relatively large, and the signal to noise ratio is higher, which is easier for subsequent algorithms to recognize, thus improving the effect of the fingerprint detection.

In an embodiment, the electronic device 300 may be a mobile phone. It can be understood that, in other embodiments, the electronic device 300 may also be a tablet PC, a notebook computer, an intelligent wearable device, an audio player, a video player, or any other electronic device having a fingerprint detection requirement.

A collecting window 302 of the fingerprint sensor 502 may be deposed on a front panel 304 of the electronic device 300, and thus it is easy for collecting the fingerprints of the users. The collecting window 302 may be at other locations of the electronic device 300, such as at a side surface or at a back surface of the electronic device 300.

Thus, the electronic device 300 may have an improved fingerprint detection effect.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”. “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

It should be understood that each part of the present disclosure may be realized by the hardware, software, firmware or their combination. In the above embodiments, a plurality of steps or methods may be realized by the software or firmware stored in the memory and executed by the appropriate instruction execution system. For example, if it is realized by the hardware, likewise in another embodiment, the steps or methods may be realized by one or a combination of the following techniques known in the art: a discrete logic circuit having a logic gate circuit for realizing a logic function of a data signal, an application-specific integrated circuit having an appropriate combination logic gate circuit, a programmable gate array (PGA), a field programmable gate array (FPGA), etc.

Those skilled in the art shall understand that all or parts of the steps in the above exemplifying method of the present disclosure may be achieved by commanding the related hardware with programs. The programs may be stored in a computer readable storage medium, and the programs comprise one or a combination of the steps in the method embodiments of the present disclosure when run on a computer.

In addition, each function cell of the embodiments of the present disclosure may be integrated in a processing module, or these cells may be separate physical existence, or two or more cells are integrated in a processing module. The integrated module may be realized in a form of hardware or in a form of software function modules. When the integrated module is realized in a form of software function module and is sold or used as a standalone product, the integrated module may be stored in a computer readable storage medium.

The storage medium mentioned above may be read-only memories, magnetic disks, CD, etc. It should be noted that, although the present disclosure has been described with reference to the embodiments, it will be appreciated by those skilled in the art that the disclosure includes other examples that occur to those skilled in the art to execute the disclosure. Therefore, the present disclosure is not limited to the embodiments.

1. A fingerprint detection circuit, configured to apply an excitation signal to a finger so as to generate finger capacitors, the fingerprint detection circuit comprising:
a signal amplifier having a negative input terminal connected with one of the finger capacitors, a positive input terminal connected with a voltage reference terminal, and an output terminal to output an output voltage according to a capacitance value of one of the finger capacitors;
a capacitor; and
a switch unit connected with the negative input terminal and the output terminal of the signal amplifier respectively, and configured to control the capacitor to be connected between the negative input terminal and the output terminal of the signal amplifier, such that the output voltage has a non-linear relationship with the capacitance value of one of the finger capacitors.

2. The fingerprint detection circuit according to claim 1, further comprising a first power supply, connected with the capacitor via the switch unit, wherein the switch unit is configured to control the first power supply to charge the capacitor or to control the capacitor to disconnect from the first power supply.

3. The fingerprint detection circuit according to claim 1, wherein the voltage reference terminal is a ground terminal.

4. The fingerprint detection circuit according to claim 1, wherein:
the switch unit comprises a first switch and a second switch;
the first switch comprises a first selecting terminal, a first power terminal and a first connecting terminal, the first selecting terminal is connected with a first terminal of the capacitor, the first power terminal is connected with a first electrode of the first power supply, and the first connecting terminal is connected with the negative input terminal of the signal amplifier;
the second switch comprises a second selecting terminal, a second power terminal and a second connecting terminal, the second selecting terminal is connected with a second terminal of the capacitor, the second power terminal is connected with a second electrode of the first power supply, and the second connecting terminal is connected with the output terminal of the signal amplifier; and
the first selecting terminal is configured to be connected with the first connecting terminal or the first power terminal, and the second selecting terminal is configured to be connected with the second connecting terminal or the second power terminal.

5. The fingerprint detection circuit according to claim 4, wherein, if the first selecting terminal is connected with the first connecting terminal and disconnected from the first power terminal, and the second selecting terminal is connected with the second connecting terminal and disconnected from the second power terminal, the capacitor is connected between the negative input terminal and the output terminal of the signal amplifier, and disconnected from the first power supply.

6. The fingerprint detection circuit according to claim 4, wherein, if the first selecting terminal is connected with the first power terminal and disconnected from the first connecting terminal, and the second selecting terminal is connected with the second power terminal and disconnected from the second connecting terminal, the first power supply is configured to charge the capacitor.

7. The fingerprint detection circuit according to claim 2, wherein the capacitance value of one of the finger capacitors is determined according to a formula of
Vo=(Vc−Vt*Cx/Ci),
wherein Vo is the output voltage, Vt is an excitation voltage of the excitation signal, Cx is the capacitance value of one of the finger capacitors, Ci is a capacitance value of the capacitor, and Vc is an voltage between the first terminal and the second terminal of the capacitor.

8. The fingerprint detection circuit according to claim 1, further comprising a second power supply, wherein:
the voltage reference terminal is an output terminal of the second power supply, the switch unit is connected with the capacitor in parallel;
if the switch unit is turned off, the capacitor is communicated with the negative input terminal and the output terminal of the signal amplifier respectively; and
if the switch unit is turned on, the capacitor is disconnected between the negative input terminal and the output terminal of the signal amplifier.

9. The fingerprint detection circuit according to claim 8, wherein the capacitance value of one of the finger capacitors is determined according to a formula of
Vo=(Vs−Vt*Cx/Ci),
wherein Vo is the output voltage, Vt is an excitation voltage of the excitation signal, Cx is the capacitance value of one of the finger capacitors, Ci is a capacitance value of the capacitor, and Vs is an voltage of the second power supply.

10. The fingerprint detection circuit according to claim 1, further comprising a sampling hold circuit and an analog-to-digital converter,
wherein the sampling hold circuit is connected between the output terminal of the signal amplifier and a terminal of the analog-to-digital converter.

11. An electronic device, comprising a fingerprint detection circuit configured to apply an excitation signal to a finger so as to generate finger capacitors, wherein the fingerprint detection circuit comprises:
a signal amplifier having a negative input terminal connected with one of the finger capacitors, a positive input terminal connected with a voltage reference terminal, and an output terminal to output an output voltage according to a capacitance value of one of the finger capacitors;
a capacitor; and
a switch unit connected with the negative input terminal and the output terminal of the signal amplifier respectively, and configured to control the capacitor to be connected between the negative input terminal and the output terminal of the signal amplifier, such that the output voltage has a non-linear relationship with the capacitance value of one of the finger capacitors.

12. The electronic device according to claim 11, the fingerprint detection circuit further comprising a first power supply, connected with the capacitor via the switch unit, wherein the switch unit is configured to control the first power supply to charge the capacitor or to control the capacitor to disconnect from the first power supply.

13. The electronic device according to claim 11, wherein the voltage reference terminal is a ground terminal.

14. The electronic device according to claim 11, wherein:
the switch unit comprises a first switch and a second switch;
the first switch comprises a first selecting terminal, a first power terminal and a first connecting terminal, the first selecting terminal is connected with a first terminal of the capacitor, the first power terminal is connected with a first electrode of the first power supply, and the first connecting terminal is connected with the negative input terminal of the signal amplifier;
the second switch comprises a second selecting terminal, a second power terminal and a second connecting terminal, the second selecting terminal is connected with a second terminal of the capacitor, the second power terminal is connected with a second electrode of the first power supply, and the second connecting terminal is connected with the output terminal of the signal amplifier; and
the first selecting terminal is configured to be connected with the first connecting terminal or the first power terminal, and the second selecting terminal is configured to be connected with the second connecting terminal or the second power terminal.
